(19) United States
(12) Patent Application Publication
(10) Pub. No.: US 2021/0108331 A1
(43) Pub. Date: Apr. 15, 2021

(54) FILM FORMING APPARATUS AND FILM FORMING METHOD

(71) Applicant: TOKYO ELECTRON LIMITED, Tokyo (JP)

(72) Inventors: Masayuki HARASHIMA, Nirasaki City, Yamanashi (JP); Yukio SANO, Nirasaki City, Yamanashi (JP); Yoshimune MISAWA, Nirasaki City, Yamanashi (JP); Hirokatsu KOBAYASHI, Nirasaki City, Yamanashi (JP)

(21) Appl. No.: 17/041,278

(22) PCT Filed: Mar. 12, 2019
(86) PCT No.: PCT/JP2019/009981

§ 371 Date: Sep. 24, 2020

(30) Foreign Application Priority Data
Mar. 26, 2018 (JP) 2018-058641

(51) Int. Cl. C30B 25/14; C30B 25/10; C30B 25/12; C30B 29/36; C23C 16/32; C23C 16/458; C23C 16/46; C23C 16/455; H01L 21/02

(52) U.S. Cl. CPC C30B 25/14; C30B 25/10; C30B 25/12; C30B 29/36; C23C 16/325; H01L 21/0262; C23C 16/46; C23C 16/455; H01L 21/02378; H01L 21/02529; C23C 16/4584

(57) ABSTRACT

A film forming apparatus for forming a silicon carbide film on a target substrate includes a substrate support on which the target substrate is placed, a gas supply mechanism configured to form a flow of a raw material gas along a direction perpendicular to a central axis of the substrate support from outside of the substrate support, and an induction coil configured to heat the target substrate. The gas supply mechanism supplies, in addition to a first Si-containing gas containing silicon without containing carbon and a first C-containing gas containing carbon without containing silicon, at least one of a second Si-containing gas having a thermal decomposition temperature higher than that of the first Si-containing gas and containing silicon without containing carbon and a second C-containing gas having a thermal decomposition temperature lower than that of the first C-containing gas and containing carbon without containing silicon, as the raw material gas.

### CROSS-REFERENCE TO RELATED APPLICATIONS

The present application claims priority based on Japanese Patent Application No. 2018-058641, filed in Japan on Mar. 26, 2018, the entire contents of which are incorporated herein by reference.

### TECHNICAL FIELD

The present invention relates to a film forming apparatus and a film forming method for forming a silicon carbide (SiC) film.

### BACKGROUND

Recently, SiC is used for electronic devices such as semiconductor power devices and the like. In an electronic device manufacturing process, a SiC film is formed by epitaxial growth in which a film having the same orientation as that of a substrate crystal is formed on a single crystal substrate.

An apparatus for forming a SiC film by epitaxial growth is disclosed in Patent Document 1. This apparatus includes a substrate support on which a SiC substrate as a substrate to be processed is placed, a rotational shaft for rotatably supporting the substrate support, and a susceptor having an inner space where the substrate support is accommodated. In the film forming apparatus disclosed in Patent Document 1, a SiC film is formed on a SiC substrate by supplying a processing gas to the SiC substrate on the substrate support in the susceptor while heating the SiC substrate by inductively heating the susceptor.

Further, in the film forming apparatus disclosed in Patent Document 1, a heat insulating material is disposed between the susceptor and the substrate support to reduce in-plane non-uniformity of a temperature of the SiC substrate on the substrate support. Accordingly, in-plane uniformity of impurity concentration of the SiC film is improved.

### Prior Art

Patent Document 1: Japanese Patent Application Publication No. 2016-100462

In Patent Document 1, the in-plane uniformity of the impurity concentration of the SiC film is improved by suppressing the in-plane non-uniformity of the temperature of the SiC substrate on the substrate support as described above. However, the temperature of the SiC substrate on the substrate support is not an only condition to be considered to improve the uniformity of the impurity concentration of the SiC film.

In view of the above, the present invention provides a new film forming method and a new film forming apparatus for forming a SiC film having in-plane uniformity of impurity concentration by adjusting a film forming condition other than a temperature of a SiC substrate on a substrate support.

### SUMMARY

In accordance with an aspect of the present invention, there is provided a film forming apparatus for forming a silicon carbide film on a substrate to be processed, including: a substrate support on which the substrate to be processed is placed; a gas supply mechanism configured to form a flow of a raw material gas along a direction perpendicular to a central axis of the substrate support from outside of the substrate support; and an induction coil configured to heat the substrate to be processed. Further, the gas supply mechanism supplies, in addition to a first Si-containing gas containing silicon without containing carbon and a first C-containing gas containing carbon without containing silicon, at least one of a second Si-containing gas having a thermal decomposition temperature higher than that of the first Si-containing gas and containing silicon without containing carbon and a second C-containing gas having a thermal decomposition temperature lower than that of the first C-containing gas and containing carbon without containing silicon, as the raw material gas.

According to the aspect of the present invention, the gas supply mechanism, which is configured to form the flow of the raw material gas along the direction perpendicular to the central axis of the substrate support from outside of the substrate support, supplies, in addition to the first Si-containing gas and the first C-containing gas, at least one of the second Si-containing gas having a thermal decomposition temperature higher than that of the first Si-containing gas and the second C-containing gas having a thermal decomposition temperature lower than that of the first C-containing gas, as the raw material gas. Therefore, in a processing space, the number of carbon atoms with respect to the number of silicon atoms as the precursor of the silicon carbide film becomes uniform, so that a silicon carbide film having an in-plane uniformity of impurity concentration can be formed.

In accordance with another aspect of the present invention, there is provided a film forming method for forming a silicon carbide film on a substrate to be processed, including: supplying a raw material gas along a direction perpendicular to a central axis of a substrate support on which the substrate to be processed is placed, from outside of the substrate support. Further, in the supplying of the raw material gas, in addition to a first Si-containing gas containing silicon without containing carbon and a first C-containing gas containing carbon without containing silicon, at least one of a second Si-containing gas having a thermal decomposition temperature higher than that of the first Si-containing gas and containing silicon without containing carbon and a second C-containing gas having a thermal decomposition temperature lower than that of the first C-containing gas and containing carbon without containing silicon, is supplied as the raw material gas.

### Effect

In accordance with the aspects of the present invention, there is provided a new film forming method and a film forming apparatus for forming a SiC film having in-plane uniformity of impurity concentration by adjusting a film forming condition other than a temperature of a SiC substrate on a substrate support.

### BRIEF DESCRIPTION OF THE DRAWINGS

FIG. 1 schematically shows a configuration of a film forming apparatus according to a first embodiment.

FIG. 2 is a cross-sectional view schematically showing a configuration in a processing chamber in the film forming apparatus of FIG. 1.

FIG. 3 shows a result of a test conducted by the present inventors.

FIGS. 4A to 4D explain operations and effects of a film forming method and the film forming apparatus according to the first embodiment.

FIG. 5 schematically shows a configuration of a film forming apparatus according to a second embodiment.

### DETAILED DESCRIPTION

Hereinafter, embodiments will be described in detail with reference to the accompanying drawings. Like reference numerals will be given to like or corresponding parts throughout this specification and the drawings, and redundant description thereof will be omitted.

### First Embodiment

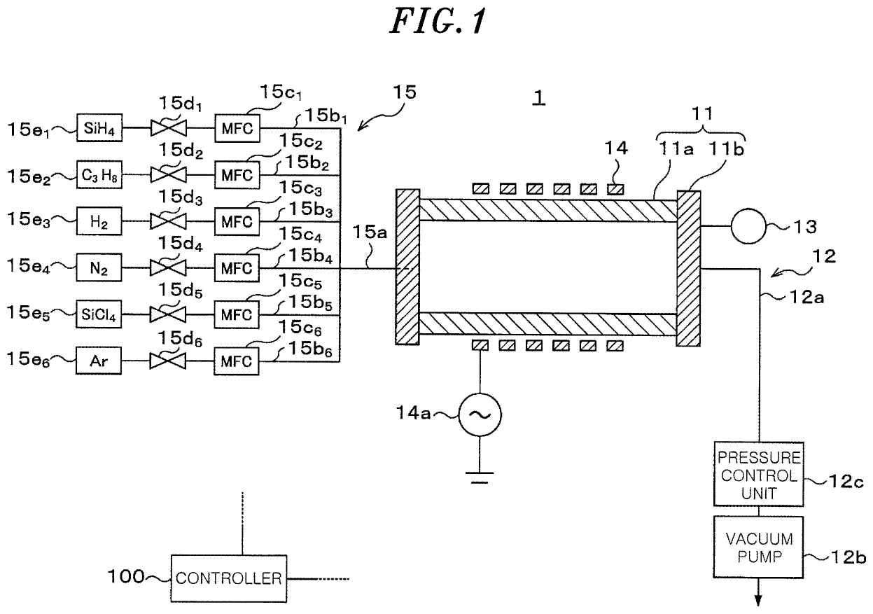

FIG. 1 schematically shows a configuration of a film forming apparatus according to a first embodiment.

A film forming apparatus 1 of FIG. 1 includes a substantially rectangular parallelepiped processing chamber 11.

A gas exhaust passage 12 is connected to the processing chamber 11, and a pressure in the processing chamber 11 can be adjusted to a predetermined depressurized state (pressure) by the gas exhaust passage 12. The gas exhaust passage 12 has a gas exhaust line 12a whose one end is connected to the processing chamber 11. The gas exhaust line 12a includes a gas exhaust manifold and the like, and a vacuum pump 12b such as a mechanical booster pump or the like is connected to the other end of the gas exhaust line 12a that is opposite to the end connected to the processing chamber. A pressure control unit 12c including an automatic pressure control (APC) valve, a proportional control valve, or the like, for controlling a pressure in the processing chamber 11 is disposed between the processing chamber 11 and the vacuum pump 12b in the gas exhaust line 12a. Further, the processing chamber 11 is provided with a pressure gauge 13, and a pressure in the processing chamber 11 is adjusted by the pressure control unit 12c based on a measurement result of the pressure gauge 13.

The processing chamber 11 has a hollow rectangular columnar processing chamber main body 11a having openings at both ends, and sidewalls 11b connected to both ends of the processing chamber main body 11a to block the openings. The processing chamber main body 11a and the sidewalls 11b are made of a dielectric material such as stainless steel, quartz, or the like.

An induction coil 14 connected to a radio frequency power supply 14a is disposed outside the processing chamber main body 11a. The induction coil 14 heats a substrate to be processed. For example, the induction coil 14 induction-heats a susceptor 23 to be described later or the like, and heats a substrate to be processed by radiant heat from the induction-heated susceptor 23.

A gas supply mechanism 15 is configured to supply a raw material gas for film formation or the like into the processing chamber 11. The gas supply mechanism 15 has a gas supply pipe 15a connected to the processing chamber 11 and gas supply pipes 15b₁ to 15b₆ connected to the gas supply pipe 15a.

The gas supply pipes 15b₁ to 15b₆ are provided with mass flow rate controllers (MFC) 15c₁ to 15c₆ and valves 15d₁ to 15d₆, respectively.

A gas supply source 15e₁ is connected to the gas supply pipe 15b₁ to supply SiH₄ gas. Similarly, gas supply sources 15e₂ to 15e6 are connected to the gas supply pipes 15b₂ to 15b₆ to supply C₃H₈ gas, H₂ gas, N₂ gas, SiCl₄ gas, and Ar gas, respectively.

In the case of forming an n-type SiC film on a SiC substrate as a substrate to be processed by epitaxial growth,

SiH₄ gas and C₃H₈ gas, H₂ gas, N₂ gas, and SiCl₄ gas are supplied as raw material gases (source gases) for film formation from the gas supply pipes 15b₁ to 15b₅ into the processing chamber 11, respectively. Further, a gas supply source for trimethylaluminum (TMA) gas, a gas supply pipe, or the like may be provided for formation of a p-type SiC film.

In the case of removing foreign substances adhered to a structure in the processing chamber 11, one of H₂ gas and Ar gas or a mixture thereof, for example, is supplied from the gas supply pipes 15b₃ and 15b₆ into the processing chamber 11.

The film forming apparatus 1 further includes a controller 100. The controller 100 is, e.g., a computer, and has a program storage unit (not shown). The program storage unit stores a program for controlling the MFCs 15c₁ to 15c₆, the valves 15d₁ to 15d₆, the radio frequency power supply 14a, the pressure control unit 12c, a rotation driving unit or an elevating unit to be described later, to perform film formation.

The program is stored in a computer-readable storage medium, e.g., a hard disk (HD), a flexible disk (FD), a compact disk (CD), a magnet optical disk (MO), a memory card, or the like, and may be installed in the controller 100 from the storage medium.

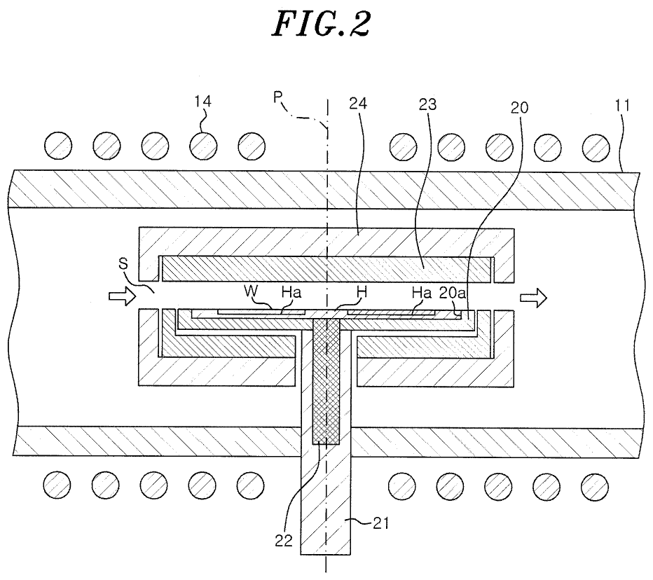

Hereinafter, a configuration in the processing chamber will be described. FIG. 2 is a cross-sectional view schematically showing the configuration in the processing chamber 11 in the film forming apparatus 1 of FIG. 1.

As shown in FIG. 2, a substrate support 20 on which an SiC substrate W (hereinafter, referred to as “substrate W”) as a substrate to be processed is placed via a holder H, a rotational shaft 21 for rotating and supporting the substrate support 20, and an elevating unit 22 for vertically moving the holder H on which the substrate W is placed are provided in the processing chamber 11. Further, a susceptor 23 as an accommodation portion is disposed in the processing chamber 11. The susceptor 23 has an inner space S for accommodating the substrate support 20, and a processing gas is supplied into the inner space S from one end of the substrate support 20 to reach the other end of the substrate support 20 through a position above the center of the substrate support 20.

The substrate support 20 is formed in a disc shape having a downwardly recessed portion 20a on an upper surface thereof and is disposed horizontally in the processing chamber 11. The holder H is fitted into the recessed portion 20a. The holder H is rotated by rotating the substrate support 20 about a central axis P of the substrate support 20 and the rotational shaft 21 by the rotational shaft 21.

The substrate support 20 is made of a conductive material that has high heat resistance and is easily heated by induction heating. The substrate support 20 is, e.g., a graphite member whose upper surface is coated with SiC.

The holder H holds a plurality of substrates W to collectively load/unload the plurality of substrates W into/from the film forming apparatus 1. A plurality of substrate supporting areas Ha on which the substrates W are respectively placed is formed on an upper surface of the holder H. The substrate supporting areas Ha are arranged at equal intervals in a circumferential direction with respect to the center of the holder H, i.e., the central axis P. The holder H is made of a conductive material that has high heat resistance and is easily heated by induction heating. The holder H is, e.g., a graphite member whose an upper surface on which the substrate W is placed is coated with SiC. Further, the holder H is formed in, e.g., a disc shape having a diameter smaller than that of the substrate support 20.

The rotational shaft 21 has one end connected to the center of the bottom portion of the substrate support 20 and the other end penetrating through the bottom portion of the processing chamber 11 and reaching a position thereunder. The rotational shaft 21 is connected to a rotation driving mechanism (not shown). The substrate support 20 is rotated by the rotation of the rotational shaft 21 by the rotation driving mechanism.

The elevating unit 22 transfers the substrate W between the substrate support 20 and a transfer device disposed outside the film forming apparatus 1. In this example, the elevating unit 22 transfers the holder H on which the substrate W is placed. The holder H, i.e., the substrate W, is vertically moved by vertically moving the elevating unit 22 by an elevation driving mechanism (not shown).

The susceptor 23 is formed in a rectangular parallelepiped shape in which openings (ports) are formed at two surfaces facing each other. A processing gas is supplied from the opening on one surface and is discharged from the opening on the other surface. In this structure, the processing gas supplied onto the substrate W is supplied and discharged along a direction parallel to the substrate W, i.e., a direction perpendicular to the central axis P.

The susceptor 23 is made of a conductive material that has high heat resistance and is easily heated by induction heating. The susceptor 23 is, e.g., a graphite member whose surface facing the substrate W is coated with SiC.

Further, a heat insulating member 24 for insulating the susceptor 23 from the processing chamber 11 is disposed at an outer periphery of the susceptor 23. The heat insulating member 24 is made of, e.g., a fibrous carbon material having a large porosity.

Although it is not illustrated, a holding structure for holding the heat insulating member 24 in a state where the heat insulating member 24 is separated from the processing chamber 11 is disposed outside the heat insulating member 24.

Hereinafter, substrate processing including film formation performed by the film forming apparatus 1 will be described.

First, the holder H on which the substrate W is placed is loaded into the processing chamber 11 (step S1). Specifically, the holder H is loaded into the processing chamber 11 from the outside of the film forming apparatus 1 through a gate valve (not shown) and positioned above the substrate support 20 by a transfer unit (not shown) disposed outside the film forming apparatus 1. Next, the elevating unit 22 is raised to support the holder H. Then, the transfer unit is retracted from the processing chamber 11 and the elevating unit 22 is lowered to place the holder H on the substrate support 20.

After the holder H is loaded, while a raw material gas and a carrier gas are supplied from the gas supply mechanism 15 in a direction perpendicular to the central axis P in the processing chamber 11, the radio frequency power is applied from the radio frequency power supply 14a to the induction coil 14 to heat the substrate W, thereby forming an n-type SiC film on the substrate W by epitaxial growth (step S2). Specifically, the valves 15d₁ to 15d₅ are opened, and SiH₄ gas, C₃H₈ gas, H₂ gas, and SiCl₄ gas are introduced into the processing chamber 11 at flow rates adjusted by the MFCs 15c₁ to 15c₅, respectively. Further, by applying the radio frequency power from the radio frequency power supply 14a to the induction coil 14, the substrate W is heated by radiation or heat conduction from the induction-heated holder H, the substrate support 20, and the susceptor 23. During the film formation, a pressure in the processing chamber 11 is, e.g., 10 Torr to 600 Torr, and a temperature of the substrate W is, e.g., 1500° C. to 1700° C.

After the film formation is completed, the holder H holding the substrate W is unloaded from the processing chamber 11 (step S3). Specifically, the valves 15d₁ to 15d₅ are closed to stop the supply of the raw material gas and the carrier gas, and the elevating unit 22 is raised to raise the holder H holding the substrate W. Next, the transfer unit disposed outside the film forming apparatus 1 is loaded into the processing chamber 11 through the gate valve and is positioned below the holder H. Then, the elevating unit 22 is lowered to transfer the holder H from the elevating unit 22 to the transfer unit, and the transfer unit is retreated from the processing chamber 11 to unload the holder H holding the substrate W from the processing chamber 11. Although the supply of the radio frequency power to the induction coil 14 may be stopped during the unloading of the substrate W, it is preferable to supply the radio frequency power to the induction coil 14 in order to control temperatures of the substrate support 20 and the susceptor 23 to be optimal in a subsequent process.

After the holder H is unloaded, the processing returns to step S1. The holder H on which another substrate W is placed is loaded into the processing chamber 11, and the processing of steps S1 to S3 is repeated.

Next, operations and effects of the present embodiment will be described.

In the conventional case of forming a SiC film by epitaxial growth, a single Si raw material gas and a single C raw material gas are often used. A monosilane (SiH₄) gas is used as an example of the Si raw material gas, and a propane (C₃H₈) gas is used as an example of the C raw material gas.

In an apparatus for forming a SiC film, the raw material gas is supplied by a downflow method or a sideflow method. In the downflow method, the raw material gas is supplied from above to be substantially perpendicular to the surface of the SiC substrate. In the sideflow method, the raw material gas is supplied from a side to be substantially parallel to the surface of the SiC substrate.

In a film forming apparatus employing the sideflow method, a holder on which a plurality of SiC substrates is placed is rotated for film growth. In this case, a length of a growth space above the SiC substrate, i.e., a distance from a supply side to an exhaust side of the processing gas in the growth space, is long. For example, when three SiC substrates, each having a diameter of 6 inches, are placed, the growth space has a length of about 340 mm. This is more than twice the length of the growth space in a down-flow type apparatus that simultaneously processes multiple SiC substrates, each having a diameter of 6 inches.

In the film forming apparatus employing the sideflow method in which the growth space is long, when an n-type SiC film is formed by epitaxial growth using only SiH₄ gas and C₃H₈ gas as raw material gases as in a conventional case, there is a difference in impurity concentration between the SiC film formed at the central portion of the holder H and the SiC film formed at the outer peripheral portion of the holder H.

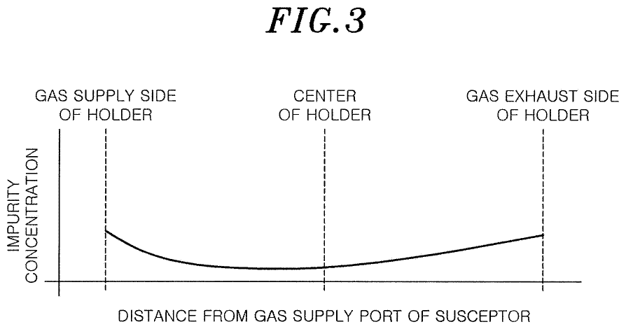

A result of one of evaluation tests conducted by the present inventors to eliminate the non-uniformity of impurity concentration is shown in FIG. 3. FIG. 3 shows a measurement result of distribution of impurity concentration of an n-type SiC film formed by using only SiH₄ gas as an Si raw material gas, only C₃H₈ gas as the C raw material gas, and N₂ gas as a dopant gas. Since the processing chamber of the film forming apparatus used in this film formation and the structure in the processing chamber are the same as those of the film forming apparatus of FIGS. 1 and 2, the reference numerals used in FIGS. 1 and 2 will be used for explanation. Further, in the film formation of which result is shown in FIG. 3, the substrate W was placed on the entire surface of the holder H, and the substrate support 20 on which the holder H was placed was not rotated.

As shown in FIG. 3, in the above-described evaluation test, the impurity concentration, i.e., the nitrogen (N) concentration, in the n-type SiC film is high on the gas supply side, decreases near the center of the holder H, i.e., directly above the rotational shaft 21, and increases on the gas exhaust side.

The non-uniformity of the impurity concentration distribution is considered to occur due to the following reasons. In other words, in the sideflow method, the supplied raw material gas is gradually heated by the radiant heat from the susceptor 23 and is rapidly heated while passing through the susceptor 23. Therefore, the temperature of the raw material gas is low on the supply side and increases toward the exhaust side. Accordingly, the decomposition amount of C₃H₈ that is decomposed into a precursor around about 800° C. is small on the supply side and increases toward the exhaust side. On the other hand, SiH₄ is decomposed into a precursor at a low temperature of about 400° C. Hence, a ratio (C/Si ratio) of the number of carbon (C) atoms in the precursor in the atmosphere to the number of silicon (Si) atoms in the same precursor is considerably low on the gas supply side, so the amount of N, i.e., a dopant of the n-type SiC film, taken into the film increases due to a site competition effect to be described later. Further, toward the exhaust side, the Si concentration decreases due to the consumption of Si by the reaction with the inner wall of the susceptor 23 or the like, whereas the decomposition amount of C₃H₈ increases as described above, which results in a high C/Si ratio. Hence, the amount of N taken into the film is reduced. In the vicinity of the exhaust side, the concentration of C₂H₂ as a precursor of C in the atmosphere is saturated, whereas the decomposition amount of N₂ increases as the temperature increases. Therefore, the amount of N taken into the film (including the amount of NHx taken into the substrate W, NHx being generated by etching unnecessary reaction products attached to the inner wall of the susceptor 23) increases again. It is presumed that the above circumstances have resulted in the non-uniform distribution of the impurity concentration.

The present inventors have studied based on the above presumption result and have found that the uniformity of the impurity concentration distribution in the SiC film can be improved by simultaneously supplying Si-containing gases having different thermal decomposition temperatures and containing Si atoms without containing C atoms. Here, the thermal decomposition temperature indicates a temperature required to decompose the Si-containing gas into a precursor state of the SiC film. For example, the thermal decomposition temperature is a temperature required to decompose SiH₄ gas as the Si-containing gas into Si atoms as precursors of the SiC film and to decompose SiCl₄ gas into SiCl₂ as precursors of the SiC film. The thermal decomposition temperature depends on the binding energy between Si atoms and other atoms in the molecule. When one of the Si-containing gases is, e.g., SiH₄ gas, a Si-containing gas, e.g., SiCl₄ gas, containing atoms whose binding energy with Si is greater than that of Si—H is simultaneously supplied together with SiH4 gas. Here, the binding energy of Si—H is 318 kJ/mol, and the binding energy of Si—Cl is 381 kJ/mol.

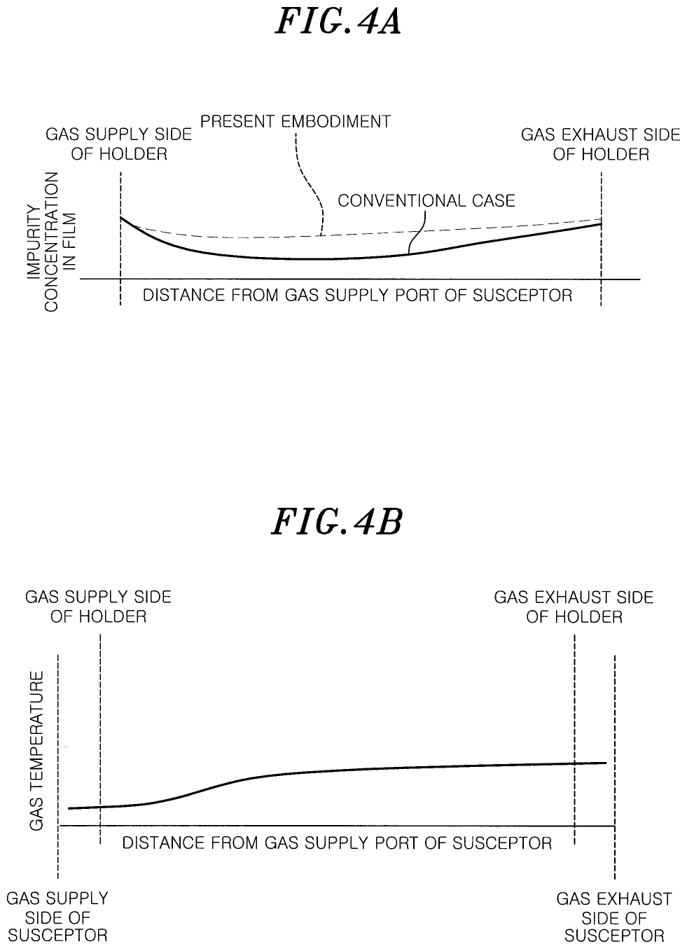

From the above, in the present embodiment, SiH₄ gas as a first Si-containing gas and tetrachlorosilane (SiCl₄) gas as a second Si-containing gas having a thermal decomposition temperature higher than that of the SiH₄ gas are supplied simultaneously for film formation. FIGS. 4A to 4D show a result of a case of performing film formation using the film forming apparatus 1 of the present embodiment by simultaneously supplying the SiH₄ gas and the SiCl₄ gas as described above in a state where the substrate W is placed on the entire surface of the holder H and the substrate support 20 on which the holder H is placed is not rotated as in the evaluation test whose result is shown in FIG. 3. In the following description, it is assumed that a total flow rate of the Si-containing gas in the film formation using the film forming apparatus 1 is equal to a flow rate of SiH₄ gas in the conventional case of using the SiH₄ gas alone.

In film formation using the film forming apparatus 1, the flow rate of SiH₄ gas is decreased compared to that in the conventional case, and the SiCl₄ gas is less likely to be decomposed into a precursor on the gas supply side. Therefore, as shown in FIG. 4, on the supply side, the amount of Si atoms in the precursor is smaller and the adsorption amount of Si atoms is decreased compared to those in the conventional case. On the other hand, the SiCl₄ gas starts to be decomposed at a position closer to the exhaust side because a decomposition temperature of the SiCl₄ gas is higher than that of the SiH₄ gas, and supplements Si atoms to a region where the Si atoms as conventional precursors are insufficient (from the central side to the exhaust side). Accordingly, a low C/Si ratio on the supply side and a high C/Si ratio on the exhaust side from the central side can be suppressed, which makes it possible to obtain uniform distribution of the C/Si ratio in the growth space. Further, since a site competition effect was dominant in taking N into the SiC film from the supply side to the vicinity of the center of the holder H, the N concentration increases near the center of the holder H and, thus, the in-plane uniformity of the N concentration in the SiN film is also improved.

The site competition indicates that when impurities are taken into the SiC film, N substitutes a C site and aluminum (Al) substitutes a Si site and, thus, C or Si competes with the impurities on the surface and the taking of dopants into the SiC film is affected. For example, in the case of a low C/Si ratio, the amount of C that competes with N is small and, thus, high N concentration is obtained.

The above-described film formation was performed in a state where the substrate support 20 was stopped without rotating. However, even when the substrate support 20 is rotated, an increase in the N concentration in a substrate region near the outer periphery of the holder H is suppressed, and the N concentration near the center of the holder H is increased. Accordingly, the in-plane uniformity of the N concentration in the SiC film is improved.

The film forming apparatus 1 can obtain the following effects (1) to (5).

(1) Generally, in an excessively low C/Si ratio state (also referred to as “Si-rich state”), Si droplets are generated and defects are caused by the Si droplets. Further, in an excessively high C/Si ratio state (also referred to as “C-rich state”), defect is generated.

Conventionally, as described above, the supply side has a low C/Si ratio and the exhaust side has a high C/Si ratio. On the other hand, in the film forming apparatus 1, the low C/Si ratio is suppressed on the supply side and the high C/Si ratio is suppressed on the exhaust side, so that the number of defects can be reduced.

(2) In the C-rich state, step bunching in which atomic steps are bunched on the surface of the substrate W/SiC film is likely to occur. Therefore, conventionally, step bunching may occur due to the C-rich state on the exhaust side. However, in the film forming apparatus 1, the C-rich state does not occur on the exhaust side, so that the occurrence of step bunching can be suppressed.

(3) Conventionally, the Si concentration in the precursor in the atmosphere on the supply side becomes excessively high locally, so that Si droplets are generated. Therefore, it is required to reduce the supply amount of the Si raw material gas, which hinders rapid growth. On the other hand, in the present embodiment, the local increase of the Si concentration on the supply side does not occur unlike the conventional case, so that high-speed growth in which the flow rate of the Si raw material gas is increased can be realized.

(4) Further, in accordance with the present embodiment, the local increase in the Si concentration on the supply side does not occur unlike the conventional case, so that a process window other than a Si raw material gas flow rate can be expanded. For example, a process window of a processing temperature (e.g., a substrate temperature or a gas temperature for film formation) or a process window of a gas supply ratio (C/Si ratio) can be expanded. More specifically, in the case of lowering the processing temperature, Si droplets are likely to be generated due to the decrease in the temperature. Therefore, in the conventional method, it is difficult to perform a process for obtaining a high-quality epitaxial film at a temperature lower than a predetermined temperature. On the other hand, in the present embodiment, a process of obtaining a high-quality epi film can be performed at a temperature lower than that in the conventional method by pre-creating an environment in which Si droplets are unlikely to occur with gas species. Similarly, in the case of increasing a gas supply ratio, the process can be performed at a gas supply ratio higher than a maximum gas supply ratio in the conventional case at which defects occur on the exhaust side because the C/Si ratio on the exhaust side of a processing space, which was high in the conventional case, can be lowered in the present embodiment.

(5) Unnecessary reaction products generated at the structure (e.g., the heat insulating member 24) on the supply side of the film forming apparatus may be brought into contact with the transfer unit for loading/unloading the SiC substrate. Therefore, cleaning is performed to remove the reaction products. In the present embodiment, the Si concentration on the supply side of the film forming apparatus 1 is lower than that in the conventional case, so that the amount of the unnecessary reaction products is small. Accordingly, the cleaning cycle can be extended and the throughput can be improved.

In the above description, SiCl₄ gas was used as the second Si-containing gas. However, it is also possible to use trichlorosilane (SiHCl₃) gas, dichlorosilane (SiH₂Cl₂) gas, monochlorosilane (SiH₃Cl) gas, tetrafluorosilane (SiF₄) gas, trifluorosilane (SiHF₃) gas, difluorosilane (SiH₂F₂) gas, and monofluorosilane (SiH₃F) gas. The binding energy of Si—F bond in SiF₄ gas and SiH₂F₂ gas is 565 kcal/mol, which is higher than that of Si—Cl bond. The thermal decomposition temperatures of SiF₄ gas and SiH₂F₂ gas are higher than those of SiCl₄ gas or SiHCl₃ gas.

Although a single gas was used as the second Si-containing gas, a plurality of gases may be mixed and used.

### Second Embodiment

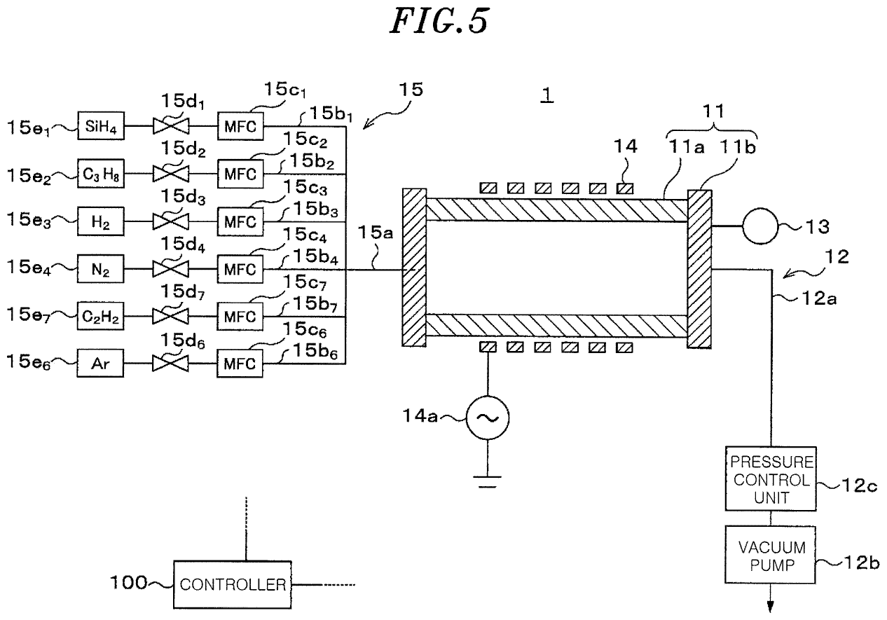

In the first embodiment, the Si-containing gases having different thermal decomposition temperatures and containing Si atoms without containing C atoms were simultaneously supplied. On the other hand, in the film forming apparatus according to the second embodiment, the C-containing gases having different thermal decomposition temperatures and containing C atoms without containing Si atoms are simultaneously supplied. Specifically, as shown in FIG. 5, the film forming apparatus 1 includes a gas supply pipe 15b₇, an MFC 15c₇, a valve 15d₇, and a gas supply source 15e₇ for supplying an acetylene (C₂H₂) gas, instead of the gas supply pipe 15b₅, the MFC 15c₅, the valve 15d₅, and the gas supply source 15e₅ of the first embodiment. Further, in the film forming apparatus 1 of the present embodiment, C₃H₈ gas as the first C-containing gas and acetylene gas as the second C-containing gas having a lower thermal decomposition temperature than that of the C₃H₈ gas are simultaneously supplied.

Also in the film forming apparatus 1 of the present embodiment, it is possible to suppress a low C/Si ratio on the supply side and a high C/Si ratio on the exhaust side from the central side, so that the distribution of the C/Si ratio in the growth space becomes uniform. Therefore, the same effects as those of the first embodiment can be obtained.

In the present embodiment, the acetylene gas was used as the second C-containing gas. However, ethylene (C₂H₄) gas or ethane (C₂H₆) gas may be used.

The above description relates to the formation of an n-type SiC film, but the present invention can also be applied to the growth of a p-type SiC film.

In the case of the p-type SiC film, unlike the n-type SiC film, the taking of Al into the p-type SiC film can be suppressed by enrichment of Si near the center of the holder H. Accordingly, the uniformity of the impurity concentration in the SiC film can be obtained.

Although the embodiments of the present invention have been described, the present invention is not limited thereto. It is obvious to those skilled in the art that various changes or modifications can be made within the scope of the technical idea described in the claims, and it is understood that these naturally fall within the technical scope of the present invention.

### DESCRIPTION OF REFERENCE NUMERALS

1: film forming apparatus
11: processing chamber
12: gas exhaust passage
14: induction coil
15: gas supply mechanism
20: substrate support
21: rotational shaft
23: susceptor
24: insulator
100: controller

1. A film forming apparatus for forming a silicon carbide film on a substrate to be processed, comprising:
a substrate support on which the substrate to be processed is placed;
a gas supply mechanism configured to form a flow of a raw material gas along a direction perpendicular to a central axis of the substrate support from outside of the substrate support; and
an induction coil configured to heat the substrate to be processed,
wherein the gas supply mechanism supplies, in addition to a first Si-containing gas containing silicon without containing carbon and a first C-containing gas containing carbon without containing silicon, at least one of a second Si-containing gas having a thermal decomposition temperature higher than that of the first Si-containing gas and containing silicon without containing carbon and a second C-containing gas having a thermal decomposition temperature lower than that of the first C-containing gas and containing carbon without containing silicon, as the raw material gas.

2. The film forming apparatus of claim 1, further comprising:
a susceptor configured to accommodate therein the substrate support.

3. The film forming apparatus of claim 1, wherein the substrate support is fixed to a rotational shaft to be rotatable via the rotational shaft.

4. The film forming apparatus of claim 3, wherein the substrate support is configured to hold a plurality of substrates to be processed in a plurality of substrate supporting areas arranged in a circumferential direction with respect to a central axis of the rotational shaft.

5. The film forming apparatus of claim 1, wherein the first Si-containing gas is a monosilane gas, and
the second Si-containing gas contains atoms bonded to silicon with energy higher than binding energy between silicon and hydrogen.

6. The film forming apparatus of claim 5, wherein the second Si-containing gas is at least one of tetrachlorosilane gas, trichlorosilane gas, dichlorosilane gas, monochlorosilane gas, tetrafluorosilane gas, trifluorosilane gas, difluorosilane gas or monofluorosilane gas.

7. The film forming apparatus of claim 1, wherein the first C-containing gas is propane gas, and
the second C-containing gas is at least one of acetylene gas, ethylene gas or ethane gas.

8. A film forming method for forming a silicon carbide film on a substrate to be processed, comprising:
supplying a raw material gas along a direction perpendicular to a central axis of a substrate support on which the substrate to be processed is placed, from outside of the substrate support,
wherein in said supplying, in addition to a first Si-containing gas containing silicon without containing carbon and a first C-containing gas containing carbon without containing silicon, at least one of a second Si-containing gas having a thermal decomposition temperature higher than that of the first Si-containing gas and containing silicon without containing carbon and a second C-containing gas having a thermal decomposition temperature lower than that of the first C-containing gas and containing carbon without containing silicon, is supplied as the raw material gas.
